(19) United States
(12) Patent Application Publication
(10) Pub. No.: US 2026/0181769 A1
(43) Pub. Date: Jun. 25, 2026

(54) MULTILAYER SUBSTRATE

(71) Applicant: Fujikura Ltd., Tokyo (JP)

(72) Inventor: Daisuke Awaji, Sakura-shi (JP)

(73) Assignee: Fujikura Ltd., Tokyo (JP)

(21) Appl. No.: 19/424,412

(22) Filed: Dec. 18, 2025

(30) Foreign Application Priority Data
Dec. 25, 2024 (JP) 2024-228543

(51) Int. Cl. H05K 1/03; H01Q 21/06; H05K 3/00

(52) U.S. Cl. CPC H05K 1/036; H01Q 21/065; H05K 3/0067

(57) ABSTRACT

A multilayer substrate includes a pair of substrates having opposing surfaces that face each other, and a thermosetting adhesive layer provided between the pair of substrates to bond the pair of substrates to each other. A conductor layer is formed on a formation surface, which is at least one of the opposing surfaces of the pair of substrates. Inclined regions, which are inclined with respect to a surface perpendicular to the formation surface, are formed on side surfaces of the conductor layer. The thermosetting adhesive layer is formed of a thermosetting adhesive material that does not become liquid at a curing temperature.

### CROSS-REFERENCE TO RELATED APPLICATION

Priority is claimed on Japanese Patent Application No. 2024-228543 filed December 25, 2024, the content of which is incorporated herein by reference.

### BACKGROUND OF THE INVENTION

### Field of the Invention

The present invention relates to a multilayer substrate.

### Description of Related Art

A multilayer substrate has, for example, a structure in which a plurality of substrates are bonded to each other through a thermosetting adhesive layer.

A conductor layer is formed on a surface of the substrate. The multilayer substrate can be manufactured by interposing a thermosetting adhesive material sheet between substrates and curing a thermosetting adhesive material by heating and pressurizing the thermosetting adhesive material (for example, see Japanese Unexamined Patent Application, First Publication No. 2003-313526).

In a basic curing process of the thermosetting adhesive material, once the thermosetting adhesive material is heated, the thermosetting adhesive material is melted and becomes highly fluid, and then curing proceeds. In a curing step, the temperature, pressure, pressure application time, and the like are adjusted such that an unevenness caused by the conductor layer on a surface of the substrate is filled with the thermosetting adhesive material when the thermosetting adhesive material is highly fluid.

### SUMMARY OF THE INVENTION

When the unevenness on the surface of the substrate is not sufficiently filled with the thermosetting adhesive material and voids remain in the curing step, interlayer peeling, swelling, and the like may occur in a reflow step, which is a subsequent step.

An object of one aspect of the present invention is to provide a multilayer substrate capable of suppressing the formation of voids in a thermosetting adhesive material in a curing step.

A multilayer substrate according to a first aspect of the present invention includes: a pair of substrates having opposing surfaces that face each other; and a thermosetting adhesive layer provided between the pair of substrates to bond the pair of substrates to each other, in which a conductor layer is formed on a formation surface, which is at least one of the opposing surfaces of the pair of substrates, an inclined region, which is inclined with respect to a surface perpendicular to the formation surface, is formed on at least one side surface of the conductor layer, and the thermosetting adhesive layer is formed of a thermosetting adhesive material that does not become liquid at a curing temperature.

According to the first aspect of the present invention, since the inclined region is formed on the side surface of the conductor layer, a recessed portion formed by the side surface of the conductor layer and the formation surface is shallower than that in a case where the side surface of the conductor layer is not inclined. Therefore, the thermosetting adhesive material tends to have a shape along the side surface of the conductor layer.

Thus, it is possible to suppress the formation of voids in the thermosetting adhesive layer. Therefore, interlayer peeling, swelling, and the like tend not to occur in the subsequent step.

In a case where the thermosetting adhesive material is not easily liquefied, the thermosetting adhesive material is not easily deformed. However, according to the first aspect of the present invention, since the thermosetting adhesive material tends to have a shape along the conductor layer, it is possible to suppress the formation of voids even in a case where a thermosetting adhesive material that is not easily deformed is used.

According to a second aspect of the present invention, in the multilayer substrate of the first aspect, the thermosetting adhesive material constituting the thermosetting adhesive layer has a viscosity of not equal to or less than 1.0E + 6 Pa·s at the curing temperature.

According to a third aspect of the present invention, in the multilayer substrate of the first or second aspect, at least one of the pair of substrates has a rigid base material.

According to a fourth aspect of the present invention, in the multilayer substrate of any one of the first to third aspects, one of the pair of substrates has a flexible base material, and the other of the pair of substrates has a rigid base material.

According to a fifth aspect of the present invention, in the multilayer substrate of any one of the first to fourth aspects, in a cross section of the conductor layer intersecting with the side surface on which the inclined region is formed, a ratio W2/W1 of a width W2 of a top side opposite to a bottom side to a width W1 of the bottom side is 9/10 or less.

According to a sixth aspect of the present invention, in the multilayer substrate of any one of the first to fifth aspects, a thickness of the conductor layer is 10 μm or more and 30 μm or less.

According to a seventh aspect of the present invention, in the multilayer substrate of any one of the first to sixth aspects, a thickness of the thermosetting adhesive layer is 15 μm or more and 50 μm or less.

According to an eighth aspect of the present invention, in the multilayer substrate of any one of the first to seventh aspects, a relative permittivity of the pair of substrates and the thermosetting adhesive layer is 3.5 or less.

According to a ninth aspect of the present invention, in the multilayer substrate of any one of the first to eighth aspects, the conductor layer forms an array antenna.

According to one aspect of the present invention, it is possible to provide a multilayer substrate capable of suppressing formation of voids in a thermosetting adhesive material in a curing step.

### BRIEF DESCRIPTION OF THE DRAWINGS

FIG. 1 is a schematic sectional view of a multilayer substrate according to a first embodiment.

FIG. 2 is a schematic sectional view of a part of the multilayer substrate according to the first embodiment.

FIG. 3 is a sectional view showing an example of a manufacturing method of the multilayer substrate according to the first embodiment.

FIG. 4 is a sectional view showing an example of the manufacturing method of the multilayer substrate according to the first embodiment.

FIG. 5 is a sectional view showing an example of the manufacturing method of the multilayer substrate according to the first embodiment.

FIG. 6 is a schematic sectional view of a multilayer substrate according to a fifth embodiment.

FIG. 7 is a schematic sectional view of a multilayer substrate according to a sixth embodiment.

FIG. 8 is a schematic sectional view of a multilayer substrate according to a seventh embodiment.

FIG. 9 is a schematic sectional view of a multilayer substrate according to a ninth embodiment.

FIG. 10 is a schematic plan view of a first substrate of a multilayer substrate according to the ninth embodiment.

FIG. 11 is a sectional view showing an example of a manufacturing method of a multilayer substrate according to a comparative example.

FIG. 12 is a sectional view showing an example of the manufacturing method of the multilayer substrate according to the comparative example.

FIG. 13 is a sectional view showing an example of the manufacturing method of the multilayer substrate according to the comparative example.

FIG. 14 is a sectional view showing an example of the manufacturing method of the multilayer substrate according to the comparative example.

### DETAILED DESCRIPTION OF THE INVENTION

Hereinafter, a multilayer substrate according to one embodiment of the present invention will be described with reference to the drawings.

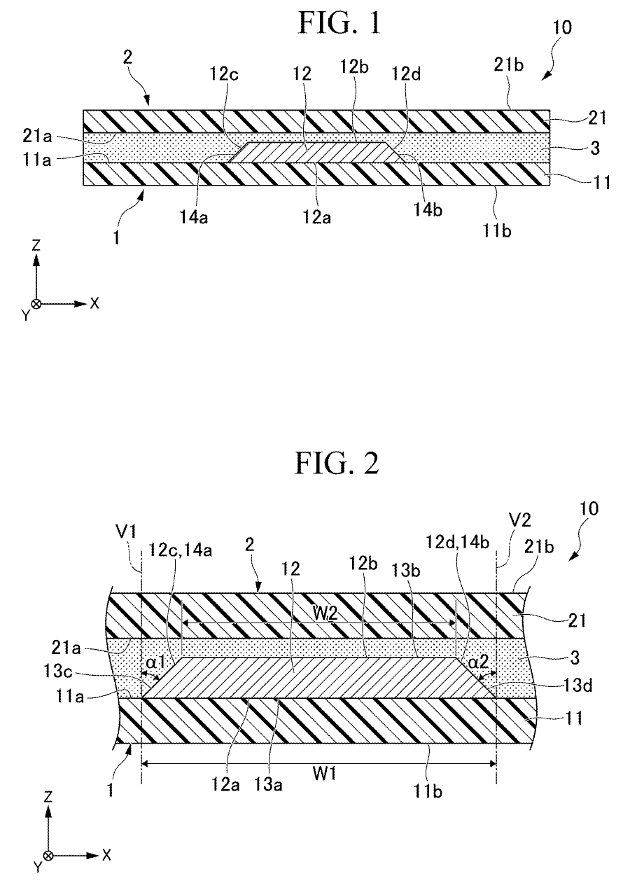

FIG. 1 is a schematic sectional view of a multilayer substrate according to a first embodiment. FIG. 2 is a schematic sectional view of a part of the multilayer substrate. FIGS. 1 and 2 show cross sections intersecting with a side surface of a conductor layer.

In the following description, the positional relationship of each configuration may be described with reference to an XYZ orthogonal coordinate system. An up-down direction in FIG. 1 is a Z direction. The Z direction is a thickness direction of a multilayer substrate 10. The upper side in FIG. 1 is a +Z side. The lower side in FIG. 1 is a -Z side. A case where the view is seen from the Z direction is referred to as a plan view. The left-right direction in FIG. 1 is an X direction. The X direction is orthogonal to the Z direction. The right side in FIG. 1 is a +X side. The left side in FIG. 1 is a -X side. The Y direction is orthogonal to the X direction and the Z direction. The X direction and the Y direction are parallel to an opposing surface 11a of the first substrate 1. The positional relationship defined herein does not limit a posture of the multilayer substrate 10 in use.

### Multilayer Substrate First Embodiment

As shown in FIG. 1, the multilayer substrate 10 includes a first substrate 1 (substrate), a second substrate 2 (substrate), and a thermosetting adhesive layer 3. The first substrate 1 and the second substrate 2 are an example of "a pair of substrates".

The first substrate 1 includes a first base material 11 and one or more conductor layers 12.

The first base material 11 is formed in a plate shape. The material of the first base material 11 is not particularly limited. The first base material 11 may be, for example, a rigid base material or a flexible base material. The first base material 11 is an insulating base material. It is preferable that the first base material 11 is formed of a low dielectric material. The relative permittivity of the first base material 11 is preferably 3.5 or less at a measurement frequency of 60 GHz. When the relative permittivity of the first base material 11 is within the range, electromagnetic characteristics of the multilayer substrate 10 can be improved. Here, in that case, a relative permittivity of the pair of substrates and the thermosetting adhesive layer is 3.5 or less.

The surface of the first base material 11 on the +Z side is the opposing surface 11a. The opposing surface 11a is a formation surface on which the conductor layer 12 is to be formed. The surface of the first base material 11 on the -Z side is an outer surface 11b. The outer surface 11b is a surface opposite to the opposing surface 11a.

The conductor layer 12 is formed of a conductive material. The conductive material includes, for example, a metal such as copper, silver, gold, or the like. The conductor layer 12 may be a metal foil, a plating layer, or the like. The conductor layer 12 may be formed of a conductive paste (conductive material).

As shown in FIG. 2, the conductor layer 12 has a bottom surface 12a, a top surface 12b, a first side surface 12c, and a second side surface 12d. The bottom surface 12a is a surface of the conductor layer 12 on the -Z side. The bottom surface 12a is in contact with the opposing surface 11a. The top surface 12b is a surface on the +Z side. The top surface 12b is a surface opposite to the bottom surface 12a. The top surface 12b is parallel to the bottom surface 12a.

The first side surface 12c is a side surface (one side surface) of the conductor layer 12 on the -X side. The second side surface 12d is a side surface (the other side surface) of the conductor layer 12 on the +X side. The first side surface 12c and the second side surface 12d can be collectively referred to as "side surfaces 12c and 12d". The side surfaces 12c and 12d may be formed to extend in the Y direction.

A first inclined region (inclined region) 14a is formed on the first side surface 12c. In the present embodiment, the first inclined region 14a is formed on the entire first side surface 12c. That is, the first inclined region 14a is a region formed from an upper end to a lower end of the first side surface 12c.

The first inclined region 14a is inclined with respect to a surface V1 perpendicular to the opposing surface 11a. The first inclined region 14a is inclined outwardly toward the opposing surface 11a. That is, the first inclined region 14a is inclined to descend toward the -X side. The term "outwardly" means a direction in which the first side surface 12c and the second side surface 12d are separated from each other. The surface V1 is, for example, a surface defined by the Y direction and the Z direction.

An inclination angle α1 of the first inclined region 14a with respect to the surface V1 is more than 0° and less than 90°. The inclination angle α1 can be set to, for example, 20° or more (for example, 30° or more). By setting the inclination angle α1 to be within the range, it is possible to suppress the formation of voids in the thermosetting adhesive material in the curing step of the thermosetting adhesive material.

The inclination angle α1 can be set to 70° or less (for example, 60° or less). By setting the inclination angle α1 to be within the range, a cross sectional area of the conductor layer 12 can be secured to be large, and the conductivity of the conductor layer 12 can be increased.

A second inclined region (inclined region) 14b is formed on the second side surface 12d. In the present embodiment, the second inclined region 14b is formed on the entire second side surface 12d. That is, the second inclined region 14b is a region formed from an upper end to a lower end of the second side surface 12d.

The second inclined region 14b is inclined with respect to a surface V2 perpendicular to the opposing surface 11a. The second inclined region 14b is inclined in a direction outwardly toward the opposing surface 11a. That is, the second inclined region 14b is inclined to descend toward the +X side. The surface V2 is, for example, a surface defined by the Y direction and the Z direction.

An inclination angle α2 of the second inclined region 14b with respect to the surface V2 is more than 0° and less than 90°. The inclination angle α2 can be, for example, 20° or more (for example, 30° or more). By setting the inclination angle α2 to be within the range, it is possible to suppress the formation of voids in the thermosetting adhesive material in the curing step of the thermosetting adhesive material.

The inclination angle α2 can be 70° or less (for example, 60° or less). By setting the inclination angle α2 to be within the range, a cross sectional area of the conductor layer 12 can be secured to be large, and the conductivity of the conductor layer 12 can be increased.

The first inclined region 14a and the second inclined region 14b can be collectively referred to as "inclined regions 14a and 14b".

A cross section of the conductor layer 12 has, for example, a trapezoidal shape having a bottom side 13a (lower base), a top side 13b (upper base), a first side 13c (first leg), and a second side 13d (second leg). The top side 13b is a side opposite to the bottom side 13a. The bottom side 13a and the top side 13b are parallel to each other.

The bottom side 13a is formed by the bottom surface 12a (the formation surface). The top side 13b is formed by the top surface 12b. The first side 13c is formed by the first side surface 12c. The second side 13d is formed by the second side surface 12d. The bottom surface 12a is a surface that overlaps the opposing surface 11a (the formation surface).

A ratio W2/W1 of a width W2 of the top side 13b (dimension in the X direction) to a width W1 of the bottom side 13a (dimension in the X direction) of the cross section of the conductor layer 12 is preferably 9/10 or less. As a result, since the inclination angles α1 and α2 of the inclined regions 14a and 14b are large, it is possible to suppress the formation of voids between the side surfaces 12c and 12d and a thermosetting adhesive material sheet 31.

The ratio W2/W1 may be, for example, 1/10 or more. Accordingly, the cross sectional area of the conductor layer 12 can be secured to be large, and the conductivity of the conductor layer 12 can be increased.

The inclination angle α2 may be equal to the inclination angle α1. When the inclination angle α1 and the inclination angle α2 are equal to each other, the cross section of the conductor layer 12 has an isosceles trapezoidal shape.

The second substrate 2 includes a second base material 21. The second base material 21 is formed in a plate shape. The material of the second base material 21 is not particularly limited. The second base material 21 may be, for example, a rigid base material or a flexible base material. The second base material 21 is an insulating base material. It is preferable that the second base material 21 is formed of a low dielectric material. When the second base material 21 is formed of a low dielectric material, the electromagnetic characteristics of the multilayer substrate 10 can be improved.

A surface of the second base material 21 on the -Z side is an opposing surface 21a. A surface of the second base material 21 on the +Z side is an outer surface 21b. The outer surface 21b is a surface opposite to the opposing surface 21a.

As shown in FIG. 1, the first substrate 1 and the second substrate 2 are disposed such that the opposing surface 11a and the opposing surface 21a face each other. The second substrate 2 is located at a position separated from the first substrate 1 on the +Z side (upward). The opposing surface 21a is parallel to the opposing surface 11a, for example.

The thermosetting adhesive layer 3 is formed of a thermosetting adhesive material. The thermosetting adhesive material is, for example, an epoxy-based resin. The thermosetting adhesive layer 3 is provided between the first substrate 1 and the second substrate 2. The thermosetting adhesive layer 3 bonds the first substrate 1 and the second substrate 2 to each other. The thermosetting adhesive layer 3 is in contact with the opposing surfaces 11a and 21a and the conductor layer 12.

The thermosetting adhesive material has a specific curing temperature. The thermosetting adhesive material has a property in which, once heated to the curing temperature, the thermosetting adhesive material becomes highly fluid, and then curing proceeds. The curing temperature of the thermosetting adhesive material is, for example, 150°C to 200°C.

The thermosetting adhesive material does not become liquid at the curing temperature. For example, at the curing temperature, the viscosity of the thermosetting adhesive material at which the fluidity is highest is, for example, not equal to or less than 1.0E + 6 Pa·s. That is, at the curing temperature, the viscosity of the thermosetting adhesive material at which the fluidity is highest exceeds 1.0E + 6 Pa·s.

It is preferable that the thermosetting adhesive layer 3 is formed of a low dielectric material. When the thermosetting adhesive material is formed of a low dielectric material, the electromagnetic characteristics of the multilayer substrate 10 can be improved.

### Manufacturing Method of Multilayer Substrate

Next, an example of a method for manufacturing the multilayer substrate 10 will be described with reference to FIGS. 3 to 5. FIGS. 3 to 5 are sectional views showing examples of the method for manufacturing the multilayer substrate 10.

### Laminating Step

As shown in FIG. 3, the thermosetting adhesive material sheet 31 is laminated on the opposing surface 21a of the second substrate 2. The thermosetting adhesive material sheet 31 is formed of a thermosetting adhesive material (for example, an epoxy-based resin). The second substrate 2 on which the thermosetting adhesive material sheet 31 is laminated and the first substrate 1 are disposed such that the opposing surface 11a and the opposing surface 21a face each other.

A laminate 5 of the first substrate 1, the second substrate 2, and the thermosetting adhesive material sheet 31 is interposed between two pressurization plates 41 and 42. A surface of the pressurization plate 41 on the +Z side is a pressurization surface 41a. A surface of the pressurization plate 42 on the -Z side is a pressurization surface 42a.

### Curing Step

### Pressurization Step

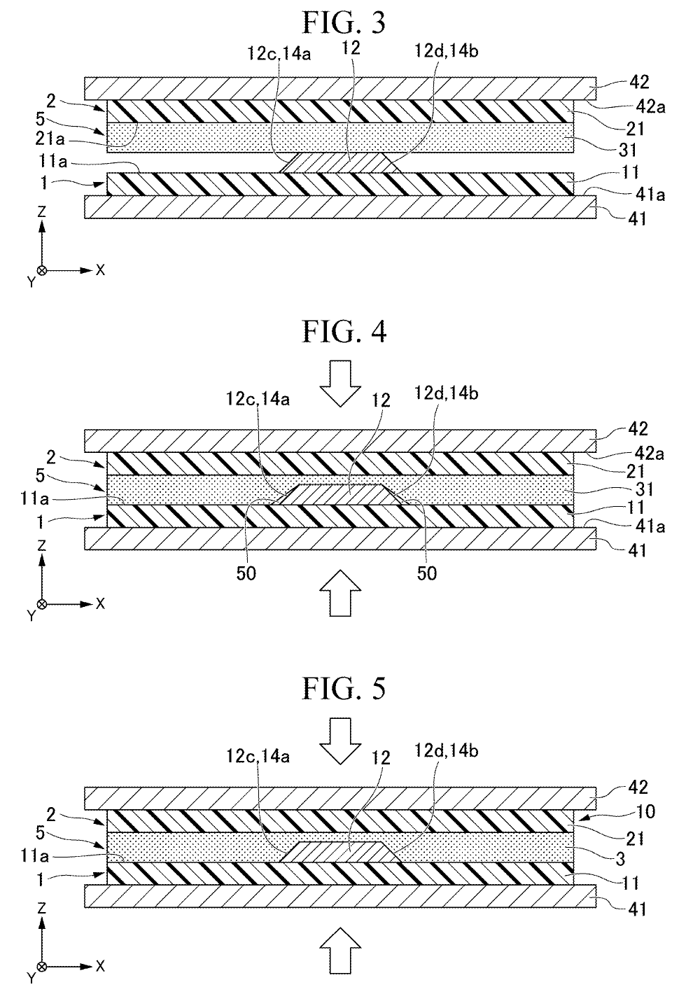

As shown in FIG. 4, a compressive force is applied to a laminate 5 in a thickness direction by the pressurization surfaces 41a and 42a of the pressurization plates 41 and 42.

The thermosetting adhesive material sheet 31 is pressed against the conductor layer 12 to be deformed according to the shape of the conductor layer 12. Since the inclined regions 14a and 14b are formed on the side surfaces 12c and 12d of the conductor layer 12, the thermosetting adhesive material sheet 31 tends to have a shape along the side surfaces 12c and 12d. Therefore, even when voids 50 are formed between the side surfaces 12c and 12d and the thermosetting adhesive material sheet 31, the voids 50 tend not to be enlarged.

### Heating Step

As shown in FIG. 5, the laminate 5 is heated while pressurizing the laminate 5 with the pressurization plates 41 and 42. A heating temperature is, for example, a curing temperature of the thermosetting adhesive material constituting the thermosetting adhesive material sheet 31 or a temperature higher than the curing temperature. Through heating, once after the thermosetting adhesive material becomes highly fluid, curing proceeds to form the thermosetting adhesive layer 3.

The thermosetting adhesive material of portions facing the side surfaces 12c and 12d of the conductor layer 12 is deformed while being highly fluid. Since the voids 50 (see FIG. 4) are small, the thermosetting adhesive material having high fluidity is deformed along the side surfaces 12c and 12d. Therefore, the voids between the thermosetting adhesive layer 3 and the conductor layer 12 are reduced or disappear.

By the above steps, the multilayer substrate 10 including the first substrate 1, the second substrate 2, and the thermosetting adhesive layer 3 is obtained.

### Subsequent Step

Components can be mounted on the multilayer substrate 10. When the components are mounted on the multilayer substrate 10, a reflow step of heating the multilayer substrate 10 may be performed. In the multilayer substrate 10, since voids tend not to be generated between the thermosetting adhesive layer 3 and the conductor layer 12, interlayer peeling, swelling, and the like caused by the voids tend not to occur in the reflow step.

### Effects of Multilayer Substrate According to Embodiment

In the multilayer substrate 10 according to the present embodiment, the inclined regions 14a and 14b are each formed on the side surfaces 12c and 12d of the conductor layer 12. Therefore, the recessed portion formed by the side surfaces 12c and 12d and the opposing surface 11a is shallower than that in a case where the side surface of the conductor layer 12 is not inclined. Therefore, the thermosetting adhesive material sheet 31 tends to have a shape along the side surfaces 12c and 12d. Accordingly, even when the voids 50 are formed between the side surfaces 12c and 12d and the thermosetting adhesive material sheet 31, the voids 50 are reduced or disappear. Therefore, the formation of voids in the thermosetting adhesive layer 3 can be suppressed (see FIG. 5). Therefore, interlayer peeling, swelling, and the like tend not to occur in the subsequent step.

In the multilayer substrate 10, the thermosetting adhesive layer 3 is formed of a thermosetting adhesive material that does not become liquid at a curing temperature. In a case where the thermosetting adhesive material is not easily liquefied, the thermosetting adhesive material sheet is not easily deformed. However, in the multilayer substrate 10 according to the present embodiment, since the thermosetting adhesive material sheet 31 tends to have a shape along the conductor layer 12, the voids tend not to be formed between the thermosetting adhesive layer 3 and the conductor layer 12. Therefore, in the multilayer substrate 10, it is possible to suppress the formation of voids even though a thermosetting adhesive material that is difficult to deform is used.

### Multilayer Substrate Second Embodiment

A multilayer substrate according to a second embodiment will be described with reference to FIG. 1.

In the multilayer substrate according to the present embodiment, the first base material 11 of the first substrate 1 and the second base material 21 of the second substrate 2 are rigid base material. The rigid base material is a hard base material having high bending stiffness. The rigid base material is formed of, for example, a fiber reinforced resin. The fiber reinforced resin is formed by impregnating reinforcing fibers with a resin. Examples of the reinforcing fiber include a glass fiber, a ceramic fiber, an aramid fiber, or the like. Examples of the resin that is impregnated in the reinforcing fiber include an epoxy-based resin, a phenol-based resin, and a urea-based resin.

In the multilayer substrate according to the present embodiment, as in the multilayer substrate 10 (see FIG. 1) according to the first embodiment, it is possible to suppress the formation of voids in the thermosetting adhesive layer 3. Therefore, interlayer peeling, swelling, and the like tend not to occur in the subsequent step.

In the multilayer substrate according to the present embodiment, the first base material 11 and the second base material 21 are rigid base materials. Since the rigid base material is not easily deformed even under pressurization and heating conditions, voids tend to remain in a recessed portion formed by the side surfaces and the opposing surface of the conductor layer. However, in the multilayer substrate according to the present embodiment, the conductor layer 12 has the inclined regions 14a and 14b, so that the thermosetting adhesive material sheet 31 tends to have a shape along the conductor layer 12. Thus, the voids tend not to be formed. Therefore, it is possible to suppress the formation of voids even in a case where the rigid base material is used.

### Multilayer Substrate Third Embodiment

A multilayer substrate according to a third embodiment will be described with reference to FIG. 1.

The multilayer substrate according to the present embodiment is different from the multilayer substrate according to the second embodiment in that the first base material 11 of the first substrate 1 is a flexible base material. That is, in the multilayer substrate, the first substrate 1 has a flexible base material, and the second substrate 2 has a rigid base material. The flexible base material is a soft base material having lower bending stiffness than the rigid base material. The flexible base material is formed of, for example, polyimide, polyester, a liquid crystal polymer, or the like.

In the multilayer substrate according to the present embodiment, as in the multilayer substrate 10 according to the first embodiment, voids tend not to be formed in the thermosetting adhesive layer 3. Therefore, interlayer peeling, swelling, and the like tend not to occur in the subsequent step. In the multilayer substrate according to the present embodiment, it is possible to suppress the formation of voids even in a case where a rigid base material is used.

### Multilayer Substrate Fourth Embodiment

A multilayer substrate according to a fourth embodiment will be described with reference to FIG. 1.

The multilayer substrate according to the present embodiment is different from the multilayer substrate according to the second embodiment in that the second base material 21 of the second substrate 2 is a flexible base material. That is, in the multilayer substrate, the first substrate 1 has a rigid base material, and the second substrate 2 has a flexible base material.

In the multilayer substrate according to the present embodiment, as in the multilayer substrate 10 according to the first embodiment, voids tend not to be formed in the thermosetting adhesive layer 3. Therefore, interlayer peeling, swelling, and the like tend not to occur in the subsequent step. In the multilayer substrate according to the present embodiment, it is possible to suppress the formation of voids even in a case where a rigid base material is used.

### Multilayer Substrate Fifth Embodiment

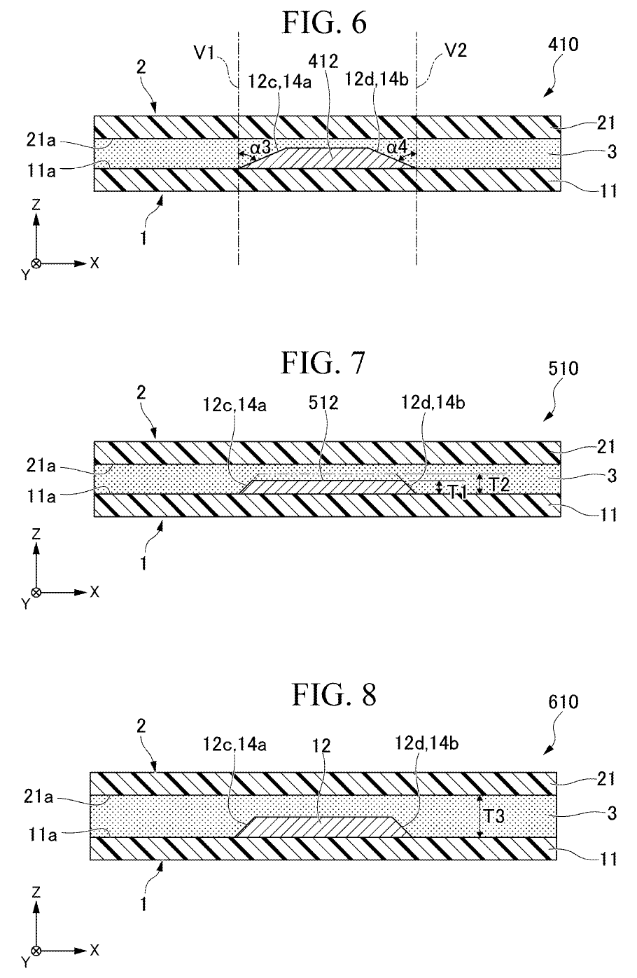

FIG. 6 is a schematic sectional view of a multilayer substrate according to a fifth embodiment. The same reference numerals are assigned to the common configurations of the multilayer substrate according to other embodiments, and the description thereof will be omitted.

As shown in FIG. 6, in a multilayer substrate 410 according to the present embodiment, inclination angles α3 and α4 of inclined regions 14a and 14b of conductor layer 412 are relatively large. The inclination angles α3 and α4 can be, for example, 45° or more. By setting the inclination angles α3 and α4 to be within the range, it is possible to suppress the formation of voids in the thermosetting adhesive material. The inclination angles α3 and α4 can be set to 80° or less. By setting the inclination angles α3 and α4 to be within the range, a cross sectional area of the conductor layer 412 can be secured to be large, and the conductivity of the conductor layer 412 can be increased.

### Multilayer Substrate Sixth Embodiment

FIG. 7 is a schematic sectional view of a multilayer substrate according to a sixth embodiment. The same reference numerals are assigned to the common configurations of the multilayer substrate according to other embodiments, and the description thereof will be omitted.

As shown in FIG. 7, in a multilayer substrate 510 according to the present embodiment, a thickness of a conductor layer 512 may be a thickness T1 that is half or less of a thickness of a thermosetting adhesive layer 3, or may be a thickness T2 that is more than half of the thickness of the thermosetting adhesive layer 3. The thickness of the conductor layer 512 may be, for example, 10 μm or more and 30 μm or less.

When the thickness of the conductor layer 512 is 10 μm or more, a cross sectional area of the conductor layer 512 can be secured to be large, and the conductivity of the conductor layer 512 can be increased. When the thickness of the conductor layer 512 is 30 μm or less, the thermosetting adhesive material sheet 31 tends to have a shape along the conductor layer 512. Thus it is possible to suppress the formation of voids.

### Multilayer Substrate Seventh Embodiment

FIG. 8 is a schematic sectional view of a multilayer substrate according to a seventh embodiment. The same reference numerals are assigned to the common configurations of the multilayer substrate according to other embodiments, and the description thereof will be omitted.

As shown in FIG. 8, in a multilayer substrate 610 according to the present embodiment, a thickness of a thermosetting adhesive layer 3 is not particularly limited. A thickness T3 of the thermosetting adhesive layer 3 may be, for example, 15 μm or more and 50 μm or less.

When the thickness T3 of the thermosetting adhesive layer 3 is 15 μm or more, the thermosetting adhesive material tends to flow in the curing step. Thus, it is possible to suppress the formation of voids in the thermosetting adhesive layer 3. When the thickness T3 of the thermosetting adhesive layer 3 is 50 μm or less, a thickness of the multilayer substrate 610 can be reduced.

### Multilayer Substrate Eighth Embodiment

A multilayer substrate according to an eighth embodiment will be described with reference to FIG. 1.

As shown in FIG. 1, in the multilayer substrate according to the present embodiment, the first base material 11, the second base material 21, and the thermosetting adhesive layer 3 are formed of a low dielectric material.

In the multilayer substrate according to the present embodiment, since the first base material 11, the second base material 21, and the thermosetting adhesive layer 3 are formed of a low dielectric material, the electromagnetic characteristics can be improved.

### Multilayer Substrate Ninth Embodiment

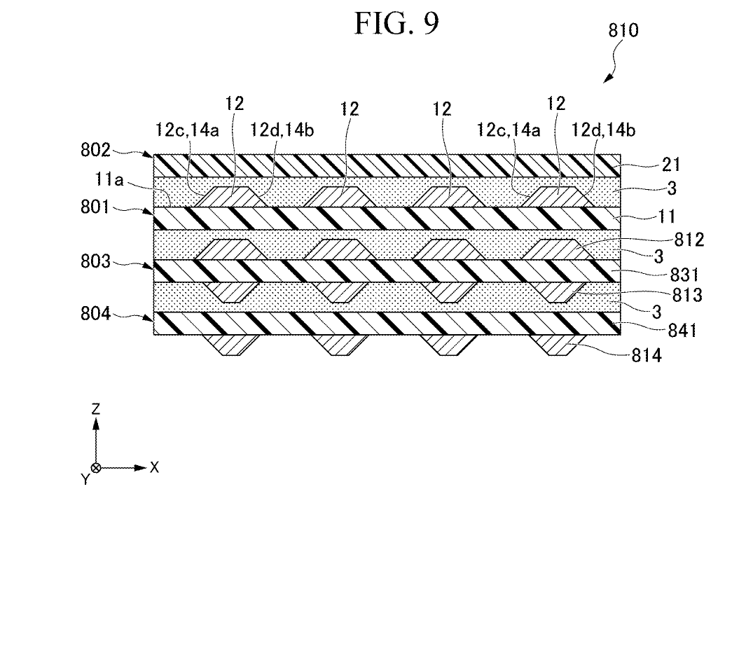

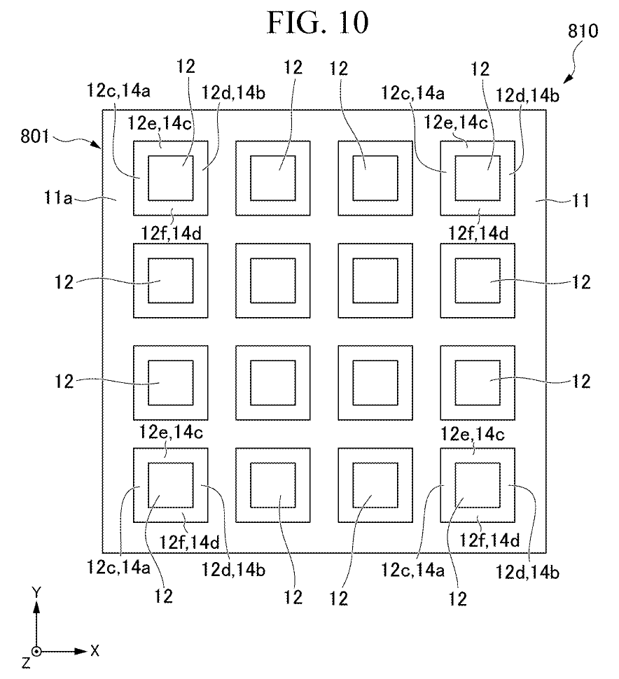

FIG. 9 is a schematic sectional view of a multilayer substrate according to a ninth embodiment. FIG. 10 is a schematic plan view of the first substrate. The same reference numerals are assigned to the common configurations of the multilayer substrate according to other embodiments, and the description thereof will be omitted.

As shown in FIG. 9, a multilayer substrate 810 includes a first substrate 801, a second substrate 802, a third substrate 803, a fourth substrate 804, and a thermosetting adhesive layer 3 provided between the adjacent substrates.

The first substrate 801 has a first base material 11 and a plurality of conductor layers 12. The second substrate 802 has the second base material 21.

The third substrate 803 has a third base material 831 and conductor layers 812 and 813. The conductor layer 812 is formed on a surface of the third base material 831 on the +Z side. The conductor layer 813 is formed on a surface of the third base material 831 on the -Z side.

The fourth substrate 804 has a fourth base material 841 and a conductor layer 814. The conductor layer 814 is formed on a surface of the fourth base material 841 on the -Z side.

As shown in FIG. 10, the plurality of conductor layers 12 of the first substrate 801 are arranged in a square lattice shape (matrix shape) on an opposing surface 11a of a first base material 11. The plurality of conductor layers 12 form an array antenna. The conductor layer 12 has a first side surface 12c, a second side surface 12d, a third side surface 12e, and a fourth side surface 12f. The first side surface 12c is a side surface of the conductor layer 12 on the -X side. The second side surface 12d is a side surface of the conductor layer 12 on the +X side. The third side surface 12e is a side surface of the conductor layer 12 on the +Y side. The fourth side surface 12f is a side surface of the conductor layer 12 on the -Y side.

A first inclined region 14a is formed on the first side surface 12c. A second inclined region 14b is formed on the second side surface 12d. A third inclined region (inclined region) 14c is formed on the third side surface 12e. A fourth inclined region (inclined region) 14d is formed on the fourth side surface 12f.

### Multilayer Substrate Comparative Example

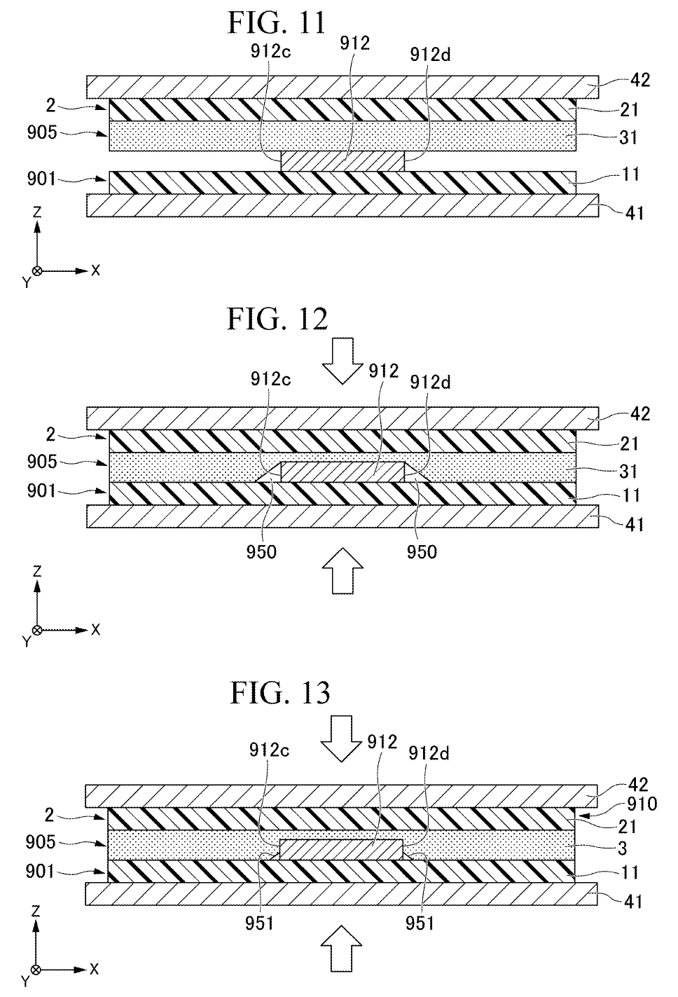

Examples of a multilayer substrate and a manufacturing method thereof according to a comparative example will be described with reference to FIGS. 11 to 14.

FIGS. 11 to 14 are sectional views showing examples of the method for manufacturing a multilayer substrate according to the comparative example. The same reference numerals are assigned to the common configurations of the multilayer substrate according to the embodiments, and the description thereof will be omitted.

### Laminating Step

As shown in FIG. 11, a first substrate 901 is different from the first substrate 1 (see FIG. 1) in that side surfaces 912c and 912d of a conductor layer 912 are not inclined.

A thermosetting adhesive material sheet 31 is laminated on a second substrate 2. A laminate 905 of the first substrate 901, the second substrate 2, and a thermosetting adhesive material sheet 31 is interposed between two pressurization plates 41 and 42.

### Curing Step

### Pressurization Step

As shown in FIG. 12, the pressurization plates 41 and 42 apply a compressive force to the laminate 905 in a thickness direction. Voids 950 are formed between the side surfaces 912c and 912d and the thermosetting adhesive material sheet 31.

### Heating Step

As shown in FIG. 13, the laminate 905 is heated while pressurizing the laminate 905 with the pressurization plates 41 and 42. The curing of thermosetting adhesive material proceeds by heating to form a thermosetting adhesive layer 3. Voids 951 remain between the thermosetting adhesive layer 3 and the conductor layer 912.

By the above steps, the multilayer substrate 910 including the first substrate 901, the second substrate 2, and the thermosetting adhesive layer 3 is obtained.

### Subsequent Step

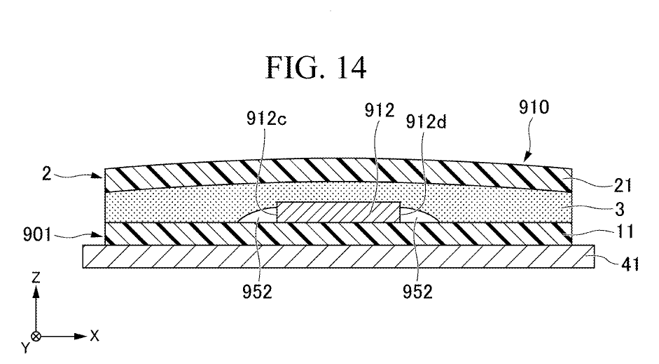

As shown in FIG. 14, when components are mounted on the multilayer substrate 910, a reflow step of heating the multilayer substrate 910 is performed. In the multilayer substrate 910, the voids 951 (see FIG. 13) expand to generate interlayer peeling portions 952 in the reflow step.

In addition, the technical scope of the present invention is not limited to the above-described embodiments, and various modifications can be made without departing from the scope of the present invention.

In the multilayer substrate 10 shown in FIG. 1, the inclined regions 14a and 14b are each formed on the first side surface 12c and the second side surface 12d of the conductor layer 12. However, the inclined region may be formed on only one of the side surfaces 12c and 12d. That is, the inclined region may be formed on at least one side surface.

In the multilayer substrate 810 shown in FIG. 10, the inclined regions 14a to 14d are each formed on the side surfaces 12c to 12f of the conductor layer 12. However, the inclined regions may be formed on at least one of the side surfaces 12c to 12f.

In the multilayer substrate 10 shown in FIG. 1, the inclination angles of the inclined regions 14a and 14b are constant in all regions. However, the inclination angles of the inclined regions may not be constant. For example, the inclined region may be a curved concave surface or a curved convex surface.

In the multilayer substrate 10 shown in FIG. 1, the conductor layer 12 is formed only on the opposing surface 11a of the opposing surfaces 11a and 21a of the first substrate 1 and the second substrate 2. However, the configuration of the conductor layer is not particularly limited. For example, the conductor layer may be formed only on the opposing surface 21a or may be formed on both the opposing surfaces 11a and 21a. That is, the conductor layer may be formed on at least one of the opposing surfaces 11a and 21a.

In the multilayer substrate 10 shown in FIG. 1, the inclined region is formed on the entire side surfaces 12c and 12d of the conductor layer 12. However, the inclined region may be formed on a partial region of the side surface of the conductor layer. For example, the inclined region may be formed in a partial region that includes an upper end of the side surface of the conductor layer and does not reach a lower end. The inclined region may be formed in a partial region that includes the lower end of the side surface of the conductor layer and does not reach the upper end.

In addition, within the scope not departing from the scope of the present invention, components in the above-described embodiment can be appropriately replaced with well-known components, and the above-described embodiment or modification examples may be appropriately combined.

What is claimed is:

1. A multilayer substrate comprising:
a pair of substrates having opposing surfaces that face each other; and
a thermosetting adhesive layer provided between the pair of substrates to bond the pair of substrates to each other,
wherein a conductor layer is formed on a formation surface, which is at least one of the opposing surfaces of the pair of substrates,
an inclined region, which is inclined with respect to a surface perpendicular to the formation surface, is formed on at least one side surface of the conductor layer, and
the thermosetting adhesive layer is formed of a thermosetting adhesive material that does not become liquid at a curing temperature.

2. The multilayer substrate according to claim 1,
wherein the thermosetting adhesive material constituting the thermosetting adhesive layer has a viscosity of not equal to or less than 1.0E + 6 Pa·s at the curing temperature.

3. The multilayer substrate according to claim 1,
wherein at least one of the pair of substrates has a rigid base material.

4. The multilayer substrate according to claim 1,
wherein one of the pair of substrates has a flexible base material, and
the other of the pair of substrates has a rigid base material.

5. The multilayer substrate according to claim 1,
wherein in a cross section of the conductor layer intersecting with the side surface on which the inclined region is formed, a ratio W2/W1 of a width W2 of a top side opposite to a bottom side to a width W1 of the bottom side is 9/10 or less.

6. The multilayer substrate according to claim 1,
wherein a thickness of the conductor layer is 10 μm or more and 30 μm or less.

7. The multilayer substrate according to claim 1,
wherein a thickness of the thermosetting adhesive layer is 15 μm or more and 50 μm or less.

8. The multilayer substrate according to claim 1,
wherein a relative permittivity of the pair of substrates and the thermosetting adhesive layer is 3.5 or less.

9. The multilayer substrate according to claim 8,
wherein the conductor layer forms an array antenna.
